(19) United States
(12) Patent Application Publication
(10) Pub. No.: US 2019/0056770 A1
(43) Pub. Date: Feb. 21, 2019

(54) ATX POWER SUPPLY AND HOUSING THEREOF

(71) Applicant: SEA SONIC ELECTRONICS CO., LTD., Taipei City (TW)

(72) Inventor: Pao-Tsun LIN, Taipei City (TW)

(21) Appl. No.: 15/677,099

(22) Filed: Aug. 15, 2017

(51) Int. Cl. G06F 1/18; H05K 5/00; H05K 5/02; H05K 7/14; H05K 7/20

(52) U.S. Cl. CPC G06F 1/189; H05K 5/0004; H05K 5/0213; H05K 7/1427; H05K 7/20136; H05K 5/0247

(57) ABSTRACT

An ATX power supply and a housing thereof. With the housing provided, a power module can be selectively hot-plugged with respect to the housing. The housing is constantly installed in a computer casing, and includes a lower plate, two side plates respectively connected to two parallel sides of the lower plate and with the lower plate jointly define an installation space, a back plate connected to the lower plate and the two side plates and provided with a plurality of through holes, and a power bridge plate disposed on the back plate and located in the installation space. The power bridge plate includes a plurality of power output ports facing the back plate and insertingly disposed in one of the through holes, and at least one bridge port facing the installation space so as to be connected with an output end of the power module.

### FIELD OF THE INVENTION

The present invention relates to an ATX power supply and a housing thereof, and particularly to a power supply implemented based on the ATX specification and including a hot-pluggable power module, and a housing for disposing the power module.

### BACKGROUND OF THE INVENTION

Current ATX power supplies are mainly applied in computers assembled or purchased by consumers, and are quite different from redundant power supplies applied to servers. For example, the Taiwan Patents No. M289211, M265701, M262961, M423290, I348606 and M507575 disclose some of the ATX power supplies.

From the above disclosures, it is known that a current ATX power supply includes only one single housing. That is to say, with respect to a consumer, apart from an electrical connecting wire of the ATX power supply revealed outside the housing, the remaining structure of the ATX power supply is disposed in the housing. Accordingly, to perform maintenance after such conventional ATX power supply is installed to a computer housing, the ATX power supply needs to be removed from the computer housing, and the housing can then be disassembled for further maintenance.

Further, when a current ATX power supply is completely manufactured, the rated power and supply voltage of the ATX power supply are restricted by circuits in the ATX power supply. In the event of a need for adjustment, the user can only discard the existing ATX power supply, resulting in resource waste.

### SUMMARY OF THE INVENTION

It is a primary object of the present invention to solve maintenance issues of a conventional ATX power supply. That is, in a conventional ATX power supply, electrical connections from the ATX power supply to a motherboard and a hard drive need to be first disconnected before maintenance can be performed.

It is another object of the present invention to solve the issue of a fixed and unadjustable powering specification after a conventional ATX power supply is completely manufactured.

To achieve the above objects, the present invention provides a housing of an ATX power supply. The housing includes a lower plate, two side plates, a back plate and a power bridge plate. The two side plates are respectively connected at two parallel sides of the lower plate, and jointly with the lower plate define an installation space and a first end opening and a second end opening respectively located at two parallel sides of the lower plate that are not installed with the two side plates. The back plate is connected to the lower plate and disposed at the second end opening, and is provided with a plurality of through holes. The power bridge plate is installed at one side of the back plate facing the installation space, and includes a plurality of power output port facing the back plate and respectively insertingly disposed in the through holes, and at least one bridge port facing the installation space. The housing allows a power module to be selectively placed in the installation space, so as to generate an electrical connection between an output end of the power module and the bridge port. The housing further includes at the other side of the lower plate an opening defined by the back plate and the two side plates. The opening is in communication with the installation space.

In one embodiment, each of the two side plates includes a limiting rib extending from its one edge that is not connected with the lower plate towards a direction of the other opposite side plate.

In one embodiment, at least one of the two side plates includes at least one positioning hole operable to be assembled with an elastic limiting member of the power module.

In one embodiment, the length of the lower plate is greater than the length of the power module.

The present invention further provides an ATX power supply. The ATX power supply includes a power module and a housing. The power module includes a casing, a circuit board distributed with a plurality of electronic components and disposed in the casing, a cooling fan disposed in the casing and electrically connected to the circuit board so as to obtain electric power, and an external power input port connected to the circuit board and revealed at one side of the casing. The circuit board includes an output end at its one other side opposite the external power input port. The casing is provided with at least one first ventilation hole at one other side opposite the side provided with the circuit board. The cooling fan is disposed correspondingly to the first ventilation hole. The housing includes comprising a lower plate, two side plates respectively connected to two parallel sides of the lower plate and jointly defining with the lower plate an installation space, a back plate connected to the lower plate and the two side plates and provided with a plurality of through holes, and a power bridge plate disposed on the back plate and located in the installation space. The power bridge plate includes a plurality of power output ports facing the back plate and respectively insertingly disposed in the through holes, and at least one bridge port facing the installation space so as be connected to the output end. The housing includes at one other side of the lower plate an opening defined by the back plate and the two side plates. The opening is in communication with the installation space. The housing allows the power module to be selectively placed in the installation space. After the power module is placed in the installation space, the output end is connected to the bridge port, and the cooling fan is disposed correspondingly to the opening and hence not covered by the housing.

In one embodiment, each of the two side plates includes a limiting rib extending from its one edge that is not connected with the lower plate towards a direction of the other opposite side plate.

In one embodiment, at least one of the two side plates of the housing includes at least one positioning hole. The casing of the power module includes at least one through hole that corresponds to the positioning hole after the power module is placed in the installation space. The power module includes an elastic limiting member. The elastic limiting member includes a connecting portion disposed in the casing, a force receiving portion and at least one limiting portion. The force receiving portion extends from the connecting portion, protrudes out of the casing and is operable to receive a force to deform the connecting portion. The at least one limiting portion extends from the connecting portion, is disposed correspondingly to the through hole and the positioning hole, and comprises a locked state in which it is penetrated through the through hole and the limiting hole to restrict the movement of the power module and a lock released state in which it is driven by the connecting portion to at least disengage from the positioning hole.

In one embodiment, one side of the casing that reveals the external power input port is provided with a plurality of second ventilation holes and a handle.

With the above disclosed embodiments of the present invention, the present invention provides following features compared to the prior art. In the ATX power supply of the present invention, maintenance of the ATX power supply can be performed or the power module can be replaced in a situation where the ATX power supply is not removed from the computer housing. Further, one side of the housing of the installation space opposite the lower plate of the housing is in a hollow form, allowing the cooling fan to dissipate heat through the hollow after the power module and the housing are assembled.

### BRIEF DESCRIPTION OF THE DRAWINGS

FIG. 1 is a structural schematic diagram of an ATX power supply according to an embodiment of the present invention;

FIG. 2 is a schematic diagram of an ATX power supply from another perspective according to an embodiment of the present invention;

FIG. 3 is a structural schematic diagram of a housing according to an embodiment of the present invention;

FIG. 4 is an assembly schematic diagram of a power module and a housing according to an embodiment of the present invention;

FIG. 5 is a first implementation schematic diagram of an elastic limiting member according to an embodiment of the present invention; and

FIG. 6 is a second implementation schematic diagram of an elastic limiting member according to an embodiment of the present invention.

### DETAILED DESCRIPTION OF THE PREFERRED EMBODIMENTS

Details and technical contents of the present invention are given with the accompanying drawings below.

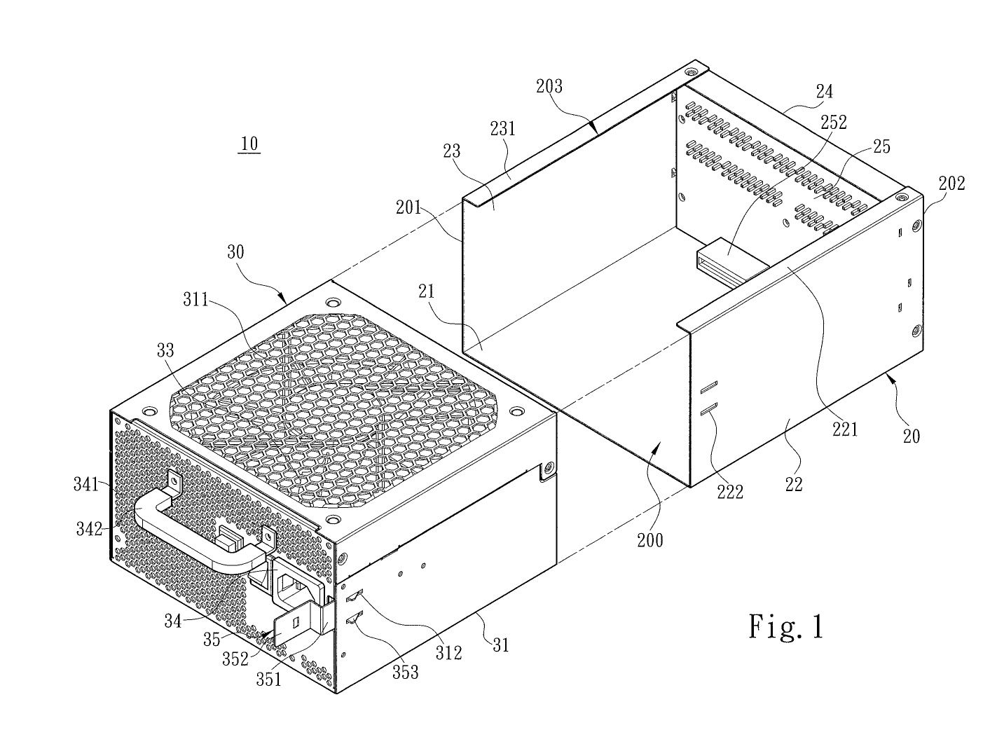

Referring to FIG. 1 to FIG. 3, the present invention provides an ATX power supply 10, which is manufactured based on the current ATX specification. The ATX power supply 10 is 150 mm in length, 140 mm in width and 86 mm in height, and is primarily divided into a housing 20 and a power module 30. The housing 20 of the ATX power supply 10 is first described. The housing 20 includes a lower plate 21, two side plates (22 and 23), a back plate 24 and a power bridge plate 25. The two side plates (22 and 23) are respectively connected to two parallel sides of the lower plate 21 such that the two side plates (22 and 23) are parallel. Further, the two side plates (22 and 23) may be manufactured from the same plate material by a mechanical process. For example, the mechanical process is stamping. Further, the two side plates (22 and 23) and the lower plate 21 may also be a plurality of plate materials connected by an assembly process using screwing or riveting. Thus, the two side plates (22 and 23) and the lower plate 21 jointly define an installation space 200, and a first end opening 201 and a second end opening 202 respectively located at two parallel sides of the lower plate 21 that are not installed with the two side plates (22 and 23). Further, the installation space 200 is in a constantly open state, and allows the power module 30 to be selectively placed therein.

Further, the other side of the installation space 200 of the housing 20 opposite the lower plate 21 is in a hollow form. Further, the housing 20 includes at the other side of the lower plate 21 an opening 203 defined by the back plate 24 and the two side plates (22 and 23) of the housing 20. The opening 203 is in communication with the installation space 200.

The back plate 24 is connected to the lower plate 21 and is disposed at one side of the lower plate 21 that is not provided with the two side plates (22 and 23). In this embodiment, the back plate 24 is installed at the second end opening 202. Further, the back plate 24 is provided with a plurality of through hole 241. The power bridge plate 25 is installed on the back plate 24, and more particularly, the power bridge plate 25 is installed at one side of the back plate 24 facing the installation space 200. The power bridge plate 25 may be distributed with electrical lines or electronic components. More specifically, the power bridge plate 25 at least includes a plurality of electrical output ports 251 facing the back plate 24 and respectively insertingly disposed in the through holes 241, and at least one bridge port 252 facing the installation space 200. The electrical output ports 251 are electrically connected to the bridge port 252 respectively via the electrical lines distributed on the power bridge plate 25. Further, the electrical output ports 251 may be in different forms, in which the numbers of pins may be adjusted according to targets of power to be outputted. Details for adjusting the numbers of pins are general knowledge in the art and shall be omitted herein. In the present invention, the form of each through hole 241 corresponds to the form of one of the electrical output ports 251 that is to be insertingly disposed in the through hole 241.

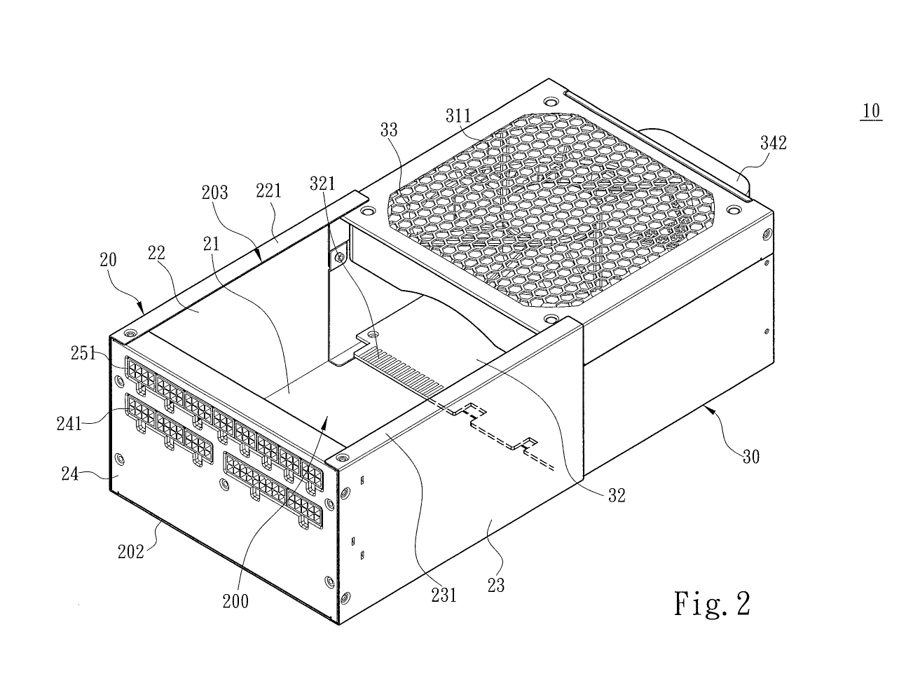

Referring to FIG. 1 and FIG. 2, the power module 30 of the present invention includes a casing 31, a circuit board 32 distributed with a plurality of electronic components and disposed in the casing 31, a cooling fan 33 disposed in the casing 31 and electrically connected to the circuit board 32 so as to obtain electrical power, and an external power input port 34 connected to the circuit board 32 and revealed at one side of the casing 31. The circuit board 32 performs power conversion or modulation by these electronic components, and includes an output end 321 at one other side opposite the external power input port 34. The output end 321 may be an electrode or a connector arranged on the circuit board 32. The casing 31 is provided with at least one first ventilation hole 311 at one other side opposite the side disposed with the circuit board 32, and the cooling fan 33 is disposed correspondingly to the first ventilation hole 311. Further, the casing 31 is provided with a plurality of second ventilation holes 341 and a handle 342 at its one side that reveals the external power input port 34. These second ventilation holes 341 coordinate with the first ventilation hole 311 to produce convection of air in the casing 31 for heat dissipation. On the other hand, the handle 342 assists a user in operating the power module 30.

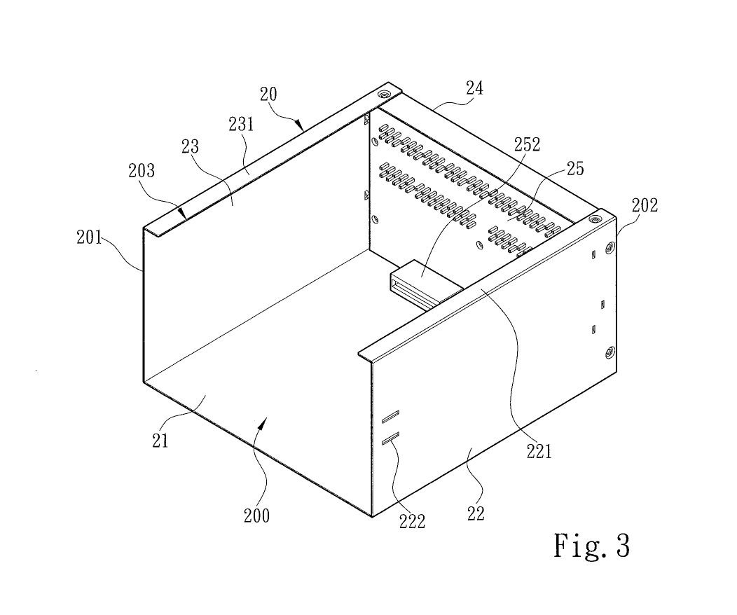

Referring to FIG. 2 and FIG. 3, the housing 20 of the present invention allows a user to selectively place the power module 30 in the installation space 200. In implementation, the housing 20 may be assembled on a computer casing (not shown) in advance, and the first end opening 201 of the housing 20 can be directly observed from the exterior of the computer casing. That is to say, the first end opening 201 is revealed at the exterior of the computer casing. During a process of placing the power module 30, the output end 321 of the power module 30 first enters the first end opening 201, the power module 30 is driven along to slide into the installation space 200, and the power module 30 moves towards the direction of the back plate 24 until an electrical connection is generated between the output end 321 and the bridge port 252. At this point, because the other side of the housing 20 opposite the lower plate 21 is hollow, the cooling fan 33 of the power module 30 is disposed correspondingly to the opening 203 and hence not covered by the housing 20, as shown in FIG. 2.

Referring to FIG. 1 and FIG. 2, in one embodiment, each of the two side plates (22 and 23) includes a limiting rib 221 or 231 extending from its one edge that is not connected with the lower plate 21 towards the other side plate (22 or 23). Further, the limiting rib 221 on the side plate 22 extends towards the side plate 23, and the limiting rib 231 on the side plate 23 extends towards side plate 22. Further, the width of each of the limiting ribs 221 and 231 may be adjusted based on requirements, given that the cooling fan 33 is not shielded by the limiting ribs 221 and 231.

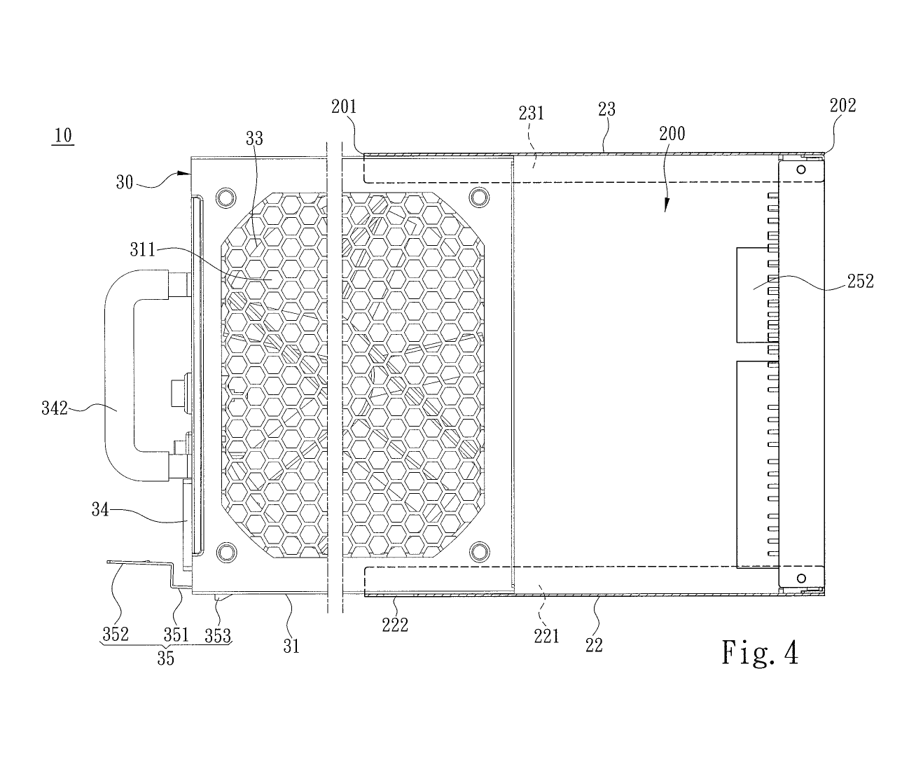

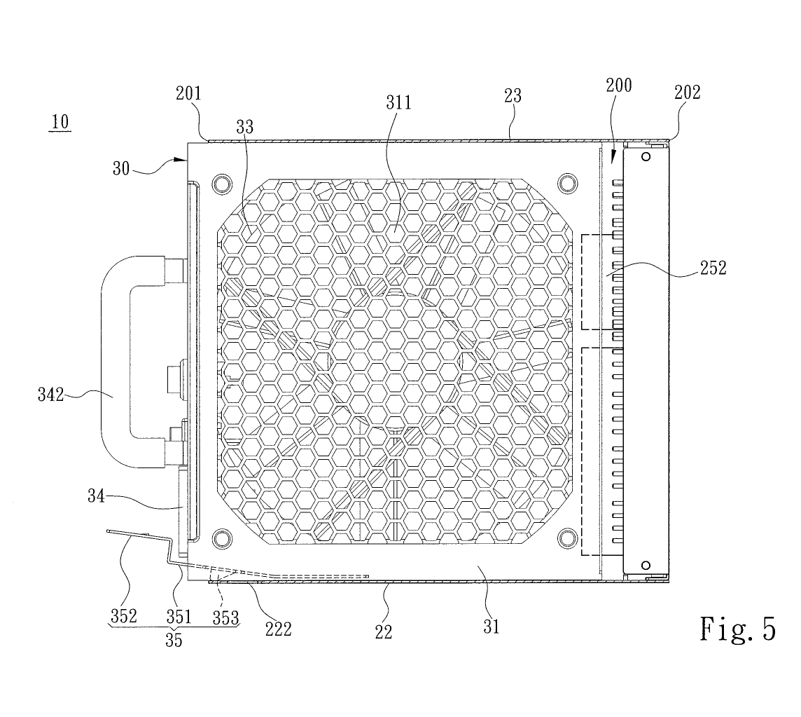

Referring to FIG. 1 to FIG. 6, in one embodiment, at least one of the two side plates (22 and 23) includes at least one positioning hole 222, and the casing 31 of the power module 30 includes at least one through hole 312 that corresponds to the positioning hole 222 after the power module 30 is placed in the installation space 200. The power module 30 further includes an elastic limiting member 35. The elastic limiting member 35 includes a connecting portion 351 disposed in the casing 31, a force receiving portion 352 extending from the connecting portion 351, protruding from the casing 31 and operable to receive force to deform the connecting portion 351, and at least one limiting portion 353 extending from the connecting portion 351 and disposed correspondingly to the through hole 312 and the positioning hole 222. The limiting portion 353 comprises a locked state in which it is penetrates through the through hole 312 and the positioning hole 222 to limit the movement of the power module 30, and a lock released state in which it is driven by the connecting portion 351 to at least disengage from the positioning hole 222. More specifically, when the force receiving portion 352 receives a force, the connecting portion 351 is deformed in response to the force received to drive the elastic limiting member 35. Assuming that the power module 30 and the housing 20 are completely installed, when the elastic limiting member 35 does not receive a force, the limiting portion 353 is maintained in the locked state over an extended period of time to limit the power module 30 from disengaging from the housing 20. When a user is to remove the power module 30 from the housing 20, the force receiving portion 352 receives a force applied by a user and causes the connecting portion 351 to deform, so as to cause the limiting portion 353 to enter the lock released state. As such, the power module 30 can be removed from the housing 20.

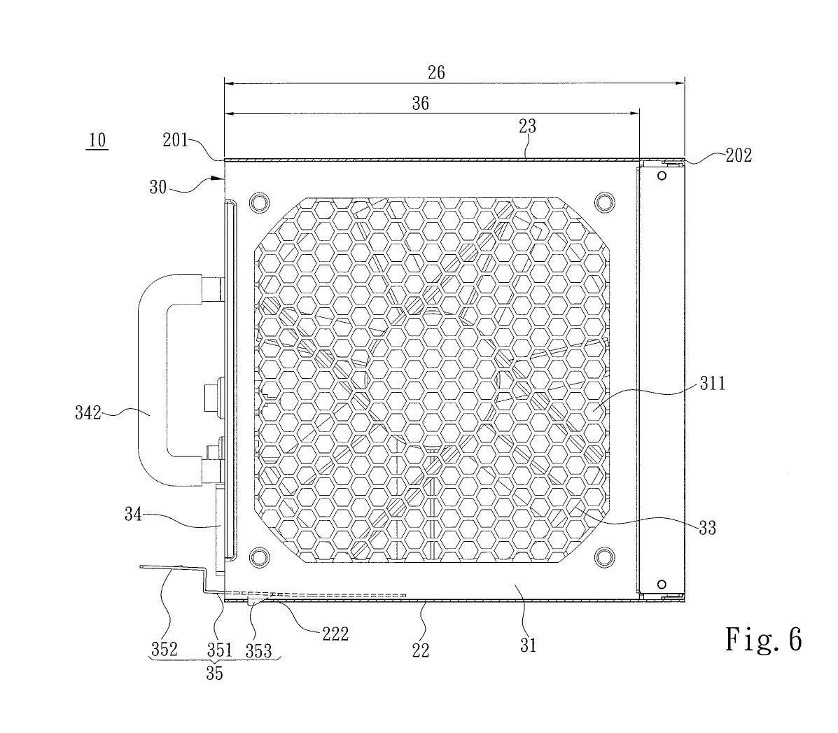

Further, the length of the power module 30 can be designed with the consideration of the lengths of the back plate 24 and the bridge port 252 on the housing 20 to prevent the power module 30 from noticeably and excessively protruding from the housing 20. In one embodiment, the length of the lower plate 21 is greater than the length of the power module 30, wherein the length of the lower plate 21 is 26 denoted in FIG. 6, and the length of the power module 30 is 36 denoted in FIG. 6.

1. A housing of an ATX power supply, comprising:
a lower plate;
two side plates, respectively connected to two parallel sides of the lower plate, the two side plates and the lower plate jointly defining an installation space and a first end opening and a second end opening respectively located at two parallel sides of the lower plate that are not installed with the two side plates;
a back plate, connected to the lower plate and disposed at the second end opening, provided with a plurality of through holes; and
a power bridge plate, installed at one side of the back plate facing the installation space, the power bridge plate comprising a plurality of power output ports facing the back plate and respectively insertingly disposed in the through holes, and at least one bridge port facing the installation space;
wherein the housing allows a power module to be selectively placed in the installation space so as to cause an output end of the power module and the bridge port to generate an electrical connection;
wherein the housing further comprises an opening facing the lower plate and defined by the back plate and the two side plates and the opening is in communication with the installation space, when the power module is placed in the installation space, a cooling fan of the power module is disposed on the opening.

2. The housing of an ATX power supply of claim 1, wherein each of the two side plates comprises a limiting rib extending from its one edge that is not connected with the lower plate towards a direction of the other side plate.

3. The housing of an ATX power supply of claim 1, wherein at least one of the two side plates comprises at least one positioning hole operable to be assembled with an elastic limiting member of the power module.

4. The housing of an ATX power supply of claim 1, wherein a length of the lower plate is greater than a length of the power module.

5. An ATX power supply comprising:
a power module, comprising a casing, a circuit board distributed with electronic components and disposed in the casing, a cooling fan disposed in the casing and electrically connected to the circuit board so as to obtain electrical power, and an external power input port connected to the circuit board and revealed at one side of the casing, the circuit board comprising an output end at its one other side opposite the external power input port, the casing comprising at least one first ventilation hole at its one other side opposite one side disposed with the circuit board, the cooling fan disposed correspondingly to the first ventilation hole; and
a housing, comprising a lower plate, two side plates respectively connected to two parallel sides of the lower plate and jointly defining with the lower plate an installation space, a back plate connected to the lower plate and the two side plates and provided with a plurality of through holes, and a power bridge plate disposed on the back lower and located in the installation space, the power bridge plate comprising a plurality of power output ports facing the back plate and respectively insertingly disposed in the through holes, and at least one bridge port facing the installation space so as to be connected to the output end, the housing comprising an opening facing the lower plate and defined by the back plate and the two side plates, the opening being in communication with the installation space;
wherein the housing allows the power module to be selectively placed in the installation space, the output end is connected with the bridge port after the power module is placed in the installation space, and the cooling fan of the power module is disposed on the opening and hence not covered by the housing.

6. The ATX power supply of claim 5, wherein each of the side plates comprises a limiting rib extending from its one edge that is not connected with the lower plate towards a direction of the other side plate.

7. The ATX power supply of claim 5, wherein at least one of the side plates of the housing comprises at least one positioning hole;
the casing of the power module comprises at least one through hole that corresponds to the positioning hole after the power module is placed in the installation space;
the power module comprises an elastic limiting member;
the elastic limiting member comprises a connecting portion disposed in the casing, a force receiving portion extending from the connecting portion, protruding from the casing and operable to receive force to deform the connecting portion, and at least one limiting portion extending from the connecting portion and disposed correspondingly to the through hole and the positioning hole;
the limiting portion comprises a locked state in which it penetrates through the through hole and the positioning hole to limit the movement of the power module, and a lock released state in which it is driven by the connecting portion to at least disengage from the positioning hole.

8. The ATX power supply of claim 7, wherein the casing comprises at its one side revealing the external power input port is provided with a plurality of second ventilation holes and a handle.

9. The ATX power supply of claim 5, wherein a length of the lower plate is greater than a length of the power module.
